(19) United States
(12) Patent Application Publication
(10) Pub. No.: US 2026/0231778 A1
(43) Pub. Date: Aug. 6, 2026

(54) METHOD OF OPTIMIZING LASER MARKING PATH

(71) Applicant: SAMSUNG ELECTRONICS CO., LTD., Suwon-si (KR)

(72) Inventors: Jimin Kim, Suwon-si (KR); Jungyoon Jang, Suwon-si (KR)

(73) Assignee: SAMSUNG ELECTRONICS CO., LTD., Suwon-si (KR)

(21) Appl. No.: 19/320,573

(22) Filed: Sep. 5, 2025

(30) Foreign Application Priority Data
Feb. 5, 2025 (KR) 10-2025-0014713

(51) Int. Cl. H01L 23/544; H01L 21/67

(52) U.S. Cl. CPC H10W 46/00; H10P 72/0614; H10W 46/103; H10W 46/401

(57) ABSTRACT

A method of minimizing a laser marking path receiving a marking character string; obtaining marking font information for each of a plurality of characters in the marking character string; determining a plurality of candidate optimal marking paths for marking the marking character string based on the marking font information, each of the plurality of candidate optimal marking paths corresponding to a laser marking device starting marking at one of the plurality of characters in the marking character string; and determining a shortest path among the plurality of candidate optimal marking paths as a final marking path.

### CROSS-REFERENCE TO RELATED APPLICATION

This application is based on and claims priority under 35 U.S.C. § 119 to Korean Patent Application No. 10-2025-0014713, filed on Feb. 5, 2025, in the Korean Intellectual Property Office, the disclosure of which is incorporated by reference herein in its entirety.

### BACKGROUND

The disclosure relates to a method of optimizing a laser marking path, and more specifically, to a method of minimizing a laser marking path for identification mark of a semiconductor package.

Semiconductor packaging is an important process of protecting semiconductor chips from external environments and connecting semiconductor chips to external circuits. Identifiers including a variety of product information may be marked on surfaces of semiconductor packages. Permanent identification information may be engraved on surfaces of semiconductor packages precisely and quickly through laser marking.

In general, laser marking technology is performed by simply setting marking paths in straight lines. When a related art laser marking technology in which marking paths are not optimized is used, the movement paths of laser unnecessarily become longer, which may increase marking time and energy consumption. Therefore, research has been conducted on technology that optimizes a laser marking path to minimize marking time and energy consumption, and ensure accurate marking quality.

### SUMMARY

One or more aspects of the disclosure provide a method of optimizing a marking path when forming an identification mark with a laser during a semiconductor package manufacturing process.

In addition, the problems to be solved by the embodiments of the disclosure are not limited to the above-mentioned problems, and other problems may be clearly understood by one of skill in the art from the description below.

According to an aspect of the disclosure, there is provided a method of minimizing a laser marking path, the method including: receiving a marking character string; obtaining marking font information for each of a plurality of characters in the marking character string; determining a plurality of candidate optimal marking paths for marking the marking character string based on the marking font information, each of the plurality of candidate optimal marking paths corresponding to a laser marking device starting marking at one of the plurality of characters in the marking character string; and determining a shortest path among the plurality of candidate optimal marking paths as a final marking path.

According to another aspect of the disclosure, there is provided a method of minimizing a laser marking path, the method including: receiving a marking character string; obtaining marking font information for each of a plurality of characters in the marking character string, the marking font information i a plurality of reference points, one or more start points, and one or more end points, each of the plurality of reference points including position information for defining a first path through which a laser marking device moves to mark a respective character among the plurality of characters, the one or more start points indicate a position at which the laser marking device starts marking of the character among the plurality of reference points, and the one or more end points indicate a position at which the laser marking device ends marking of the character corresponding to the one or more start points; determining a plurality of candidate optimal marking paths for marking the marking character string based on the marking font information, each of the plurality of candidate optimal marking paths corresponding to a laser marking device starting marking at one of the plurality of characters in the marking character string; and determining a shortest path among the plurality of candidate optimal marking paths as a final marking path.

According to an aspect of the disclosure, there is provided a method of minimizing a laser marking path, the method including: receiving laser marking regions and marking character strings to be marked respectively on the laser marking regions; obtaining marking font information for each of a plurality of characters in the marking character strings; determining a plurality of candidate optimal marking paths for marking the marking character strings in the laser marking regions based on the marking font information, each of the plurality of candidate optimal marking paths corresponding to a laser marking device starting marking at one of the plurality of characters in the marking character strings; and determining a shortest path among the plurality of candidate optimal marking paths as a final marking path.

### BRIEF DESCRIPTION OF DRAWINGS

Embodiments will be more clearly understood from the following detailed description taken in conjunction with the accompanying drawings in which:

FIG. 1 is a cross-sectional view schematically illustrating a semiconductor package and a laser marking device, according to an embodiment;

FIG. 2 is a plan view schematically illustrating the semiconductor package of FIG. 1;

FIG. 3 is a diagram schematically illustrating a controller of a laser marking device, according to an embodiment;

FIG. 4 is a flowchart schematically illustrating a method of optimizing a laser marking path, according to an embodiment;

FIG. 5 is a flowchart illustrating an algorithm for determining a final marking path, according to an embodiment;

FIG. 6 illustrates a portion of marking font information for each character, according to an embodiment;

FIG. 7 is a conceptual diagram illustrating a laser marking path with respect to a marking character string according to a method of optimizing a laser marking path, according to an embodiment;

FIG. 8 is a conceptual diagram for explaining a laser marking path using unidirectional scanning;

FIG. 9 is a conceptual diagram for explaining a laser marking path using bidirectional scanning;

FIG. 10 is a graph for comparing laser marking speeds using a method of optimizing a laser marking path according to an embodiment, unidirectional scanning, and bidirectional scanning;

FIG. 11 is a flowchart schematically illustrating a method of optimizing a laser marking path, according to an embodiment;

FIG. 12 is a flowchart illustrating an algorithm for determining a final marking path, according to an embodiment;

FIG. 13 is a plan view schematically illustrating a semiconductor package according to an embodiment; and

FIG. 14 is a flowchart schematically illustrating a method of optimizing a laser marking path, according to an embodiment.

### DETAILED DESCRIPTION OF THE EMBODIMENTS

Hereinafter, embodiments of the disclosure will be described in detail with reference to the accompanying drawings. The same reference numerals are used for the same components on the drawings, and redundant descriptions thereof are omitted.

The disclosure should not be construed as limited to the embodiments to be described below and may be embodied in various other forms. The embodiments below are not provided to fully complete the inventive concept but rather to sufficiently convey the scope of the inventive concept to one of skill in the art. Herein, the singular forms of the components may include the plural forms unless the context clearly indicates the context clearly indicates otherwise.

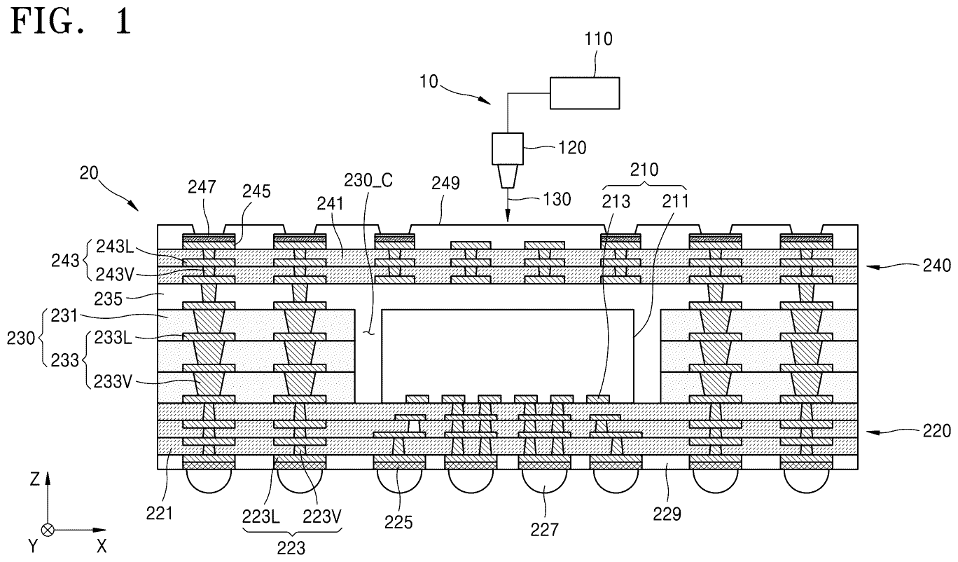

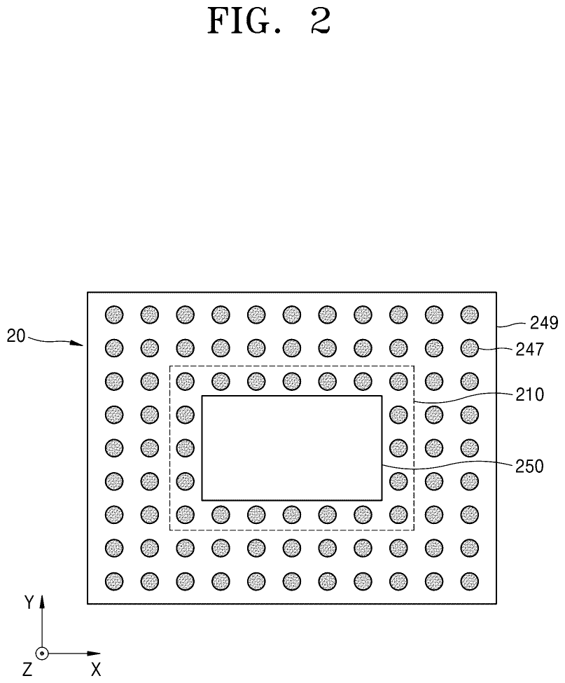

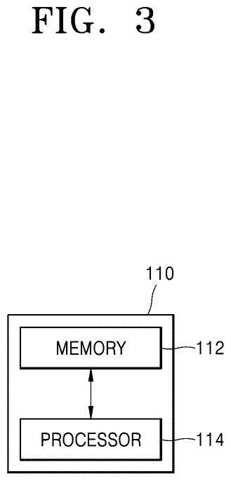

FIG. 1 is a cross-sectional view schematically illustrating a semiconductor package 20 and a laser marking device 10 according to an embodiment. FIG. 2 is a plan view schematically illustrating the semiconductor package 20 of FIG. 1. FIG. 3 is a diagram schematically illustrating a controller 110 of the laser marking device 10 according to an embodiment.

Referring to FIGS. 1 to 2, the semiconductor package 20 may include a semiconductor chip 210, a first redistribution structure 220, a connection structure 230, a second redistribution structure 240, and a marking region 250.

Hereinafter, unless specifically defined, a direction parallel to an upper surface of the first redistribution structure 220 is defined as a first horizontal direction (X direction), a direction perpendicular to the upper surface of the first redistribution structure 220 is defined as a vertical direction (Z direction), and a direction perpendicular to the first horizontal direction (X direction) and the vertical direction (Z direction) is defined as a second horizontal direction (Y direction).

The connection structure 230 of the semiconductor package 20 may be provided on the first redistribution structure 220. For example, the connection structure 230 may be electrically connected to a part of the first redistribution pattern 223 of the first redistribution structure 220. The connection structure 230 may electrically connect the second redistribution structure 240 to the first redistribution structure 220.

The connection structure 230 may include a cavity 230_C extending from an upper surface to a lower surface. The semiconductor chip 210 may be mounted inside a cavity 230_C of the connection structure 230. The cavity 230_C may be formed in the center of the connection structure 230 as shown in FIG. 1. However, the disclosure is not limited thereto, and as such, the number the cavities 230_C and or the arrangement of cavities 230_C may be different than the illustrated in FIG. 1. For example, the semiconductor package 20 include more than one cavity 230_C

The connection structure 230 may include a plurality of base layers 231 and a via structure 233. In some embodiments, a plurality of base layers 231 may include first to third base layers stacked in the vertical direction (Z direction). For example, the connection structure 230 may have a multilayer structure including the first to third base layers. The plurality of base layers 231 may surround at least a part of the via structure 233.

In some embodiments, each of the plurality of base layers 231 may include a phenol resin, a thermosetting resin such as an epoxy resin, a thermoplastic resin such as polyimide, or an insulating material in which at least one resin selected from these resins is impregnated with a core material including an inorganic filler and/or glass fiber.

For example, each of the plurality of base layers 231 may include, but is not limited to, prepreg, Ajinomoto build-up film (ABF), Frame Retardant 4(FR4 ), tetrafuntional epoxy, polyphenylene ether, bismaleimide triazine (BT), epoxy/polyphenylene oxide, thermount, cyanate ester, polyimide, liquid crystal polymer, or a combination thereof.

The via structure 233 may include a plurality of connection pads 233L and a plurality of connection vias 233V. The plurality of connection pads 233L may extend in a horizontal direction (X direction and/or Y direction) on an upper surface or a lower surface of each of the plurality of base layers 231.

In some embodiments, the plurality of connection pads 233L may include a first connection pad, a second connection pad, a third connection pad, and a fourth connection pad located at different vertical levels. The first connection pad located at the lowermost end among the plurality of connection pads 233L may be connected to the first redistribution structure 220. The fourth connection pad located at the uppermost end among the plurality of connection pads 233L may be connected to the second redistribution structure 240.

The plurality of connection vias 233V may extend in the vertical direction (Z direction) inside the plurality of base layers 231. The plurality of connection vias 233V may connect the plurality of connection pads 233L located at different vertical levels. In some embodiments, the plurality of connection vias 233V may include a first connection via, a second connection via and a third connection via located at different vertical levels.

In some embodiments, each of the plurality of connection pads 233L may include, but is not limited to, an electrically depleted (ED) copper foil, a rolled-annealed (RA) copper foil, a stainless steel foil, an aluminum foil, an ultra-thin copper foil, sputtered copper or copper alloys. In some embodiments, each of the plurality of connection vias 233V may include, but is not limited to, copper, nickel, stainless steel, beryllium copper, or a combination thereof.

The semiconductor chip 210 of the semiconductor package 20 may be provided on the first redistribution structure 220. The semiconductor chip 210 may be mounted in the cavity 230_C of the connection structure 230, and may be provided to be spaced apart from an inner wall of the cavity 230_C. The semiconductor package 20 includes one semiconductor chip 210 in FIG. 1. However, the disclosure is not limited thereto, and as such, the number of semiconductor chips 210 may be more two or more.

In some embodiments, the semiconductor chip 210 may include a logic chip or a memory chip. The logic chip may be a microprocessor. For example, the logic chip may be a central processing unit (CPU), a controller, or an application specific integrated circuit (ASIC). The memory chip may be a volatile memory chip such as dynamic random access memory (DRAM) or static random access memory (SRAM), or a nonvolatile memory chip such as phase-change random access memory (PRAM), magnetoresistive random access memory (MRAM), ferroelectric random access memory (FeRAM), or resistive random access memory (RRAM).

The semiconductor chip 210 may include a semiconductor substrate 211 and a chip pad 213. In some embodiments, the semiconductor substrate 211 may include, but is not limited to, silicon (Si). In addition, the semiconductor substrate 211 may include, but is not limited to, a semiconductor element such as germanium (Ge), or a compound semiconductor such as silicon carbide (SiC), gallium arsenide (GaAs), indium arsenide (InAs), and indium phosphide (InP).

The chip pad 213 may be provided on a lower surface of the semiconductor substrate 211. The chip pad 213 may be electrically connected to a plurality of individual elements of various types included in an active surface. In addition, the chip pad 213 may be electrically connected to at least a part of a first via pattern 223V located at the uppermost end among a plurality of first via patterns 223V of the first redistribution structure 220.

The first redistribution structure 220 of the semiconductor package 20 may expand input/output terminals of the semiconductor chip 210 to an outer region of the semiconductor chip 210. The first redistribution structure 220 may include a plurality of first insulating layers 221 and the first redistribution pattern 223.

The first insulating layers 221 may each include an insulating material, for example, a photo imageable dielectric (PID) resin. In this case, the first insulating layers 221 may each further include an inorganic filler. For example, the first insulating layers 221 may include the same materials, but the disclosure is not limited thereto, and as such, the first insulating layers 221 may include different materials. For example, two of more layers of the first insulating layers 221 may be formed of different materials.

The first redistribution pattern 223 may include the first via pattern 223V and the first line pattern 223L. The first line pattern 223L may be provided on at least one of upper and lower surfaces of the first insulating layers 221. The first via pattern 223V may penetrate the first insulating layers 221 to be connected to a part of the first line pattern 223L. The number and arrangement of the first insulating layers 221, the first via patterns 223V, and the first line patterns 223L constituting the first redistribution structure 220 are not limited to those shown in the drawings, and may be modified in various ways in some embodiments.

The first redistribution pattern 223 may include a conductive material. For example, the conductive material may include, but is not limited to, copper (Cu), aluminum (Al), silver (Ag), tin (Sn), gold (Au), nickel (Ni), lead (Pb), titanium (Ti), or alloys thereof.

The lower surface of the semiconductor chip 210 may be in direct contact with the first insulating layers 221 which are the uppermost layers among the first insulating layers 221. The first redistribution pattern 223 may serve to expand the input/output terminals of the semiconductor chip 210 to the outside. That is, the semiconductor package 20 may be a fan-out semiconductor package.

In some embodiments, the first redistribution structure 220 may be formed on the lower surface of the semiconductor chip 210 by a chip-first process. In the order in which the first redistribution structure 220 is formed, the first via pattern 223V may have a tapered shape with a horizontal width increasing away from the semiconductor chip 210.

In some embodiments, the semiconductor package 20 may further include a first passivation layer 229. The first passivation layer 229 may be provided on a lower surface of the first redistribution structure 220 and may serve to protect the first redistribution structure 220. The first passivation layer 229 may include an insulating material. For example, the insulating material may include, but is not limited to, a thermosetting resin or a thermoplastic resin.

For example, at least a part of the first line pattern 223L may be exposed through openings of the first passivation layer 229. The exposed first line pattern 223L may be electrically connected to first pads 225 provided inside the opening. External connection terminals 227 may be electrically connected to the first pads 225, respectively.

The external connection terminals 227 may connect the semiconductor package 20 to a main board of a separate electronic device on which the semiconductor package 20 is mounted. The external connection terminals 227 may include a conductive material. For example, the conductive material may include, but is not limited to, solder, tin (Sn), silver (Ag), copper (Cu), or aluminum (Al). The external connection terminals 227 may be changed to various shapes such as a land, a bump, a pillar, a pin, etc., in addition to a ball shape.

A molding layer 235 of the semiconductor package 20 may be provided to fill space between the connection structure 230 in the cavity 230_C and the semiconductor chip 210, and may cover an upper surface of each of the connection structure 230 and the semiconductor chip 210.

The molding layer 235 may include, but is not limited to, an epoxy-based material, a thermosetting material, a thermoplastic material, etc. For example, the molding layer 235 may include, but is not limited to, ABF, FR-4, BT, Epoxy Molding Compound (EMC), etc.

The second redistribution structure 240 of the semiconductor package 20 may be provided on the connection structure 230 and the semiconductor chip 210. The second redistribution structure 240 may include second insulating layers 241, a second redistribution pattern 243, a bump pad 245, a metal pad 247, and a second passivation layer 249.

The second insulating layers 241 may each include an insulating material, for example, a PID resin. In this case, the second insulating layers 241 may each further include an inorganic filler. The second insulating layers 241 may include the same materials, but the disclosure is not limited thereto, and as such, the second insulating layers 241 may include different materials. For example, two of more layers of the second insulating layers 241 may be formed of different materials.

The second redistribution pattern 243 may include a second via pattern 243V and a second line pattern 243L. The second line pattern 243L may be provided on at least one of upper and lower surfaces of the second insulating layers 241. The second via pattern 243V may extend in the vertical direction (Z direction) inside the second insulating layers 241 or inside the molding layer 235. The second via pattern 243V may connect the second line patterns 243L located at different vertical levels to each other, or may connect at least a part of the second line pattern 243L located at the lowermost end to at least a part of the connection pad 233L located at the uppermost end of the connection structure 230. In some embodiments, the second via pattern 243V may have a tapered shape with a horizontal width increasing away from the upper surface of the semiconductor chip 210. The number and arrangement of the second insulating layers 241, the second via patterns 243V, and the second line patterns 243L constituting the second redistribution structure 240 are not limited to those shown in the drawings, and may be modified in various ways in some embodiments.

In some embodiments, the second redistribution pattern 243 may include, but is not limited to, copper (Cu), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

The bump pad 245 may be provided on the upper surface of the second insulating layer 241. The bump pad 245 may be provided on the second redistribution pattern 243 to be electrically connected to the second redistribution pattern 243. For example, the bump pad 245 may be connected to the second via pattern 243V located at the uppermost end among the second via patterns 243V.

A plurality of bump pads 245 may be provided on the upper surface of the second insulating layer 241. The bump pad 245 may include, but is not limited to, copper (Cu). However, the bump pad 245 is not limited thereto, and may include the same material as the second redistribution pattern 243.

The metal pad 247 may be provided on the bump pad 245. The metal pad 247 may be provided to be in contact with an upper surface of the bump pad 245. The metal pad 247 may have a dual structure including a first metal pad 247a and a second metal pad 247b provided on the first metal pad 247a. The first metal pad 247a and the second metal pad 247b may include, but is not limited to, Ni and Au, respectively, but are not limited thereto.

The second passivation layer 249 may be provided on the upper surface of the second insulating layer 241. The second passivation layer 249 may serve to protect the second insulating layer 241, the second redistribution pattern 243, the bump pad 245, and the metal pad 447. The second passivation layer 249 may include an insulating material. For example, the second passivation layer 249 may include, but is not limited to, ABF, FR-4, BT, and EMC, but is not limited thereto.

The marking region 250 is a position where a marking character string is formed by the laser marking device 10. The marking region 250 may be provided on the second passivation layer 249. However, the position of the marking region 250 is not limited thereto, and may be changed in various ways. In an example case in which the semiconductor package 20 does not include the second passivation layer 249 and the second redistribution structure 240, the marking region 250 may be formed directly on the molding layer 235. In another example case in which the semiconductor package 20 includes a separate marking panel on the second passivation layer 249 or the molding layer 235, the marking region 250 may be formed on the marking panel. The marking region 250 may be formed at a position sufficiently understood by one of ordinary in the art according to the structure of the semiconductor package 20.

A fan-out panel level package (FOPLP) type semiconductor package 20 in which the first redistribution pattern 223 expands the input/output terminal of the semiconductor chip 210 to the outside is described with reference to FIGS. 1 and 2. However, the disclosure is not limited thereto, and as such, the target semiconductor package is not limited to the form of the semiconductor package 20 of FIGS. 1 and 2 in an example caes in which laser marking are formed by using the laser marking device 10 described below.

Referring back to FIGS. 1 and 3, the laser marking device 10, which is a device forming laser marking on the semiconductor package 20, may form a marking character string by irradiating a laser on the upper surface of the semiconductor package 20. The laser marking device 10 may include the controller 110 and a laser source 120. In some example cases, the controller may be referred to as a control unit and the laser source may be referred to as a laser source unit. The control unit may be implemented by a hardware, a software or a combination of hardware and software. The laser source unit may be implemented by one or more hardware components configured to irradiate a laser beam.

For example, the controller 110 may control the laser source 120, adjust the wavelength or energy of a laser 125, and form a marking character string according to a marking path. According to an embodiment, the controller 110, which is an electronic device, may include a memory 112 and one or more processors 114.

The memory 112 may store computer readable instructions. In an example case in which the instructions stored in the memory 112 are executed by the processor 114, the processor 114 may process operations defined by the instructions. The memory 112 may include, for example, RAM, DRAM, SRAM, or other types of nonvolatile memory known in the art. For example, the memory 112 may store a laser marking path optimization algorithm or an optimized marking path. In addition, the memory 112 may store, for example, font information for each character.

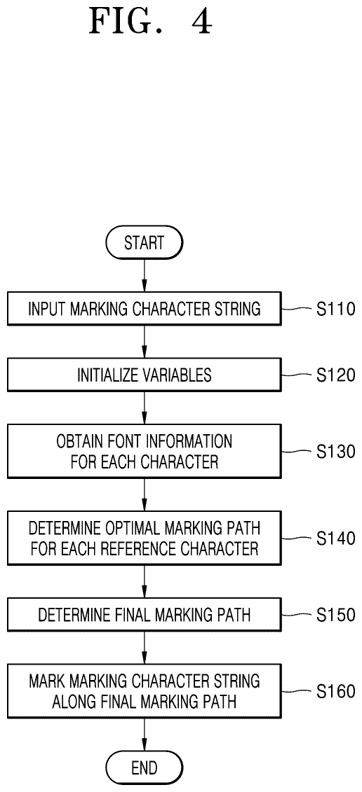

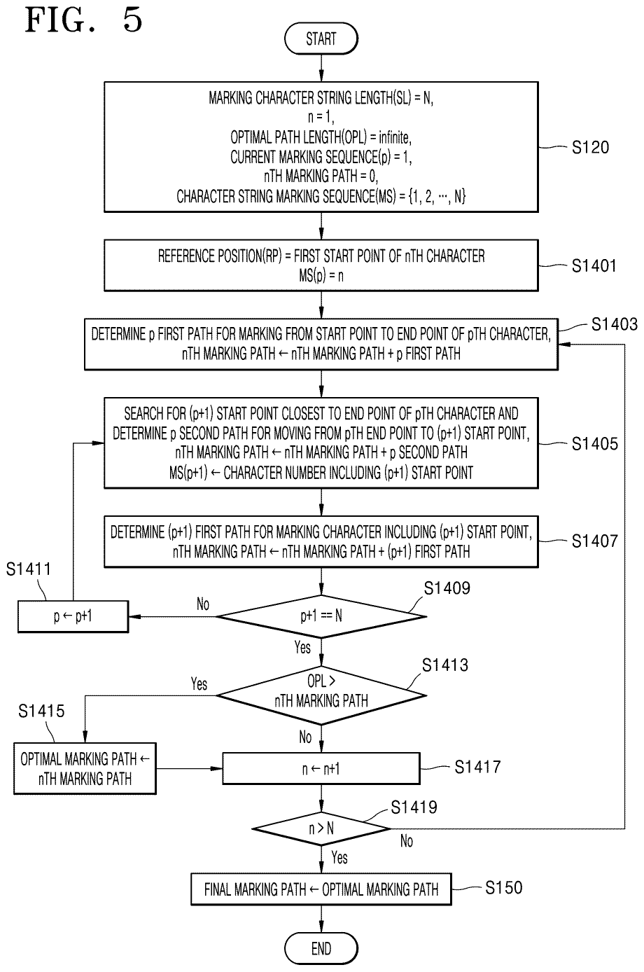

The one or more processors 114 according to an embodiment may control the overall operations of the laser marking device 10. The processor 114 may be a device implemented as hardware including a circuit with a physical structure for executing desired operations. Desired operations may include codes or instructions included in a program. The device implemented as hardware may include a microprocessor, a CPU, a graphics processing unit (GPU), a processor core, a multi-core processor, a multiprocessor, an ASIC, a field programmable gate array (FPGA), a natural processing unit (NPU), etc. Operations performed by the processor 114 will be described below with reference to FIGS. 4 and 5.

The laser source 120 may be controlled by the controller 110 to generate the laser 125. The wavelength and energy of the laser 125 generated by the laser source 120 may be controlled by the controller 110. The controller 110 may irradiate the laser 125 to the marking region 250 according to the marking path so that the laser generated by the laser source 120 may form a marking character string.

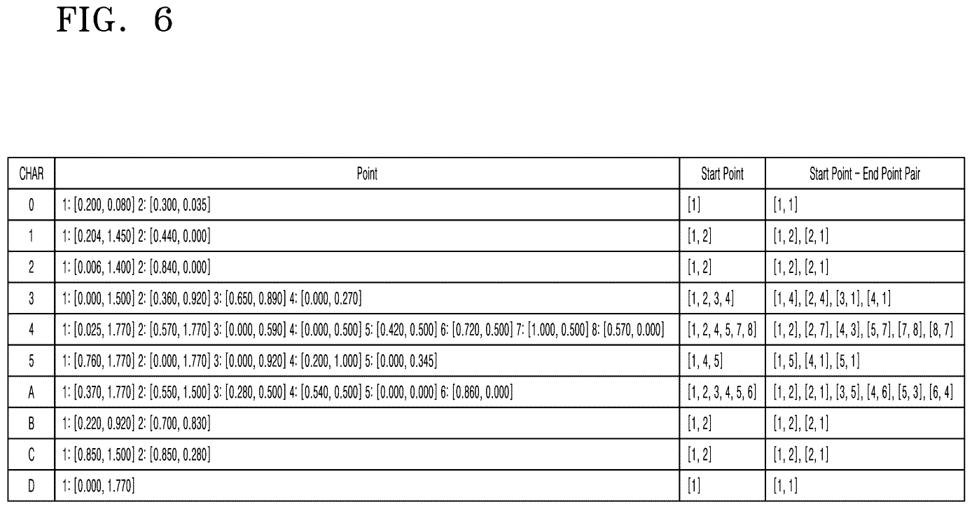

FIG. 4 is a flowchart schematically illustrating a method of optimizing a laser marking path according to an embodiment. FIG. 5 is a flowchart illustrating an algorithm for determining a final marking path according to an embodiment. FIG. 6 illustrates a portion of marking font information for each character according to an embodiment.

According to an embodiment, each of operations of optimizing the laser marking path of FIG. 4 may be performed by the processor 114 of FIG. 3.

In operation S110, the method may include inputting marking character string. For example, a marking character string for marking may be input or received. The marking character string includes characters to be marked on the marking region 250 (FIG. 2) of the semiconductor package 20 through the laser marking device 10 of FIGS. 1 to 3. The marking character string may be an identification mark including a product name, manufacturer information, etc. of a semiconductor package.

In operation S120, the method may include initializing one or more variables. For example, variables necessary to determine the optimal marking path are initialized. Here, the one or more variables may include information about the length of the marking character string, the marking sequence of characters included in the marking character string, and a reference character which is a character starting marking among the characters included in the marking character string. For example, the one or more variables may be initialized to set the length of the marking character string to the number of characters of the marking character string input in operation S110. In addition, for example, the one or more variables may be initialized to set the marking sequence to the sequence in which the characters of the marking character string are arbitrarily listed, and set the reference character to a first character.

In operation S130, the method may include obtaining font information for each character. Referring to FIG. 6, the font information for each character may include a plurality of points for each character. For example, the plurality of may include a start point, and an end point for each character. Here, each of the plurality of points may be position information of a reference point for defining a path through which a laser marking device moves to mark a corresponding character for each character. For example, when marking the number 1, a point at the uppermost end and a point at the lowermost end of the number 1 may be used as points, and coordinate information of each point may be included in the font information. According to some embodiments, the characters may include Arabic numerals 0 to 9 and English alphabets A to Z, and points of each character may be predetermined. However, the disclosure is not limited thereto, and as such, the characters may include other types of characters and characters from other languages. Each character may include a different number of points. For example, the number 1 includes two points and the number 3 may include four points.

The start point for each character may refer to a point at which a marking path of a corresponding character starts among points of the corresponding character. For example, the start point for each character may be determined as a first point of the corresponding character. However, in some embodiments, the start point for each character is not determined as one of points of the corresponding character, but a plurality of points may be start points. Here, the plurality of start points may be referred to as candidate start points. For example, the number 1 includes two points, and both two points may be start points. However, while the number 5 includes five points, only three points may be start points to form an efficient path for marking the number 5.

The end point for each character may refer to a point at which marking ends when the corresponding character starts to be marked at each start point. One end point may correspond to each start point such that the start point and the end point may form a pair. As such, each character may include a plurality of end points. Here, the plurality of end points may be referred to as candidate start points

According to an embodiment, the font information for each character including information about the plurality of points, the start points, and the end points for each character may be predetermined information. For example, the font information for each character may be predetermined information according to a laser marking device or according to the size and font of a character to be marked.

In FIG. 4, operations S110, S120, and S130 are shown as separate operations, but are not necessarily performed in sequence, and operations S120 and S130 may be performed simultaneously with operation S110, or operation S130 may be performed before operation S120.

In operation S140, the method may include determining an optimal marking path for each reference character. Here, the reference character may refer to a character that starts marking a marking character string. In an example case in which the marking character string is “5D9RV1”, the reference character is “5” when marking starts at a first character “5”, and the reference character is “D” when marking starts at a second character “D”. In the marking character string “5D9RV1” including a total of six characters, a total of six optimal marking paths may be determined by determining the optimal marking path when marking starts in each character.

In some embodiments, the optimal marking path may mean that the length of the marking path is the minimum. For example, the optimal marking path may be determined such that the sum of first paths through which a laser marking device moves to mark each character included in the marking character string and second paths through which the laser marking device moves from a completely marked character to a next character is minimized.

In some embodiments, the optimal marking path may refer to a marking path through which the minimum time is required for the laser marking device to mark along the marking path. For example, the optimal marking path may be determined such that the sum of first times required for the laser marking device to mark each character included in the marking character string and second times required for the laser marking device to move from the completely marked character to the next character is minimized.

In operation S150, the method may include determining a final marking path. For example, the most optimal path among the optimal marking paths determined in operation S140 may be determined as the final marking path. For example, the shortest path among the final marking paths may be determined as the final marking path. For example, a path through which the shortest time is required for the laser marking device to mark among the final marking paths may be determined as the final marking path.

In operation S160, the method may include marking the character string on the marking region 250 based on the final marking path. For example, the laser marking device 10 (see FIG. 1) may mark the marking character string on the marking region 250 (see FIG. 1) of the semiconductor package 20 (see FIG. 1) with a laser along the determined final marking path.

FIG. 5 illustrates an algorithm for performing operations S120, S140, and S150 of FIG. 4 in more detail. Each of operations of optimizing the laser marking path of FIG. 5 may be performed by the processor 114 of FIG. 3.

In operation S120, variables necessary to determine the optimal marking path are initialized. In an example case in which the number of characters in the marking character string is N, an initial value of a marking character string length SL is determined to be N. An initial value of an optimal path length OPL is determined to be infinite. An initial value of a variable n for determining which of the characters to start marking is determined to be 1, and an initial value of a variable p for indicating the sequence of the characters determining the current marking path is determined to be 1. Here, n and p may be integers greater than or equal to 1 and less than or equal to N. An nth marking path is a variable that refers to a path for marking all characters included in the marking character string from an nth character, and the initial value is determined to be 0. Here, the path may refer to a length of a path to be marked. A character string marking sequence MS may refer to a permutation for indicating the sequence of N characters. In an example case in which marking is performed from the first character in sequence listed in the character string, it may be expressed as the character string marking sequence MS={1, 2, . . . , N}. The initial value of the character string marking sequence MS may be arbitrarily determined as MS={1, 2, . . . , N}.

In an example case in which the marking character string is “5D9RV1”, it may be determined that the marking character string length SL=6, the optimal path length OPL=infinite, n=1, current marking sequence p=1, first marking path=0, and the character string marking sequence MS={1, 2, 3, 4, 5, 6}.

Operations S1401 to S1419 are detailed operations of operation S140 of FIG. 4. Hereinafter, the first path may refer to a path through which the laser marking device moves to draw one character, and the second path may refer to a path through which the laser marking device jumps and moves from one character to a marking position of another character.

In operation S1401, a reference position RP is defined as a first start point of the nth character, and an element corresponding to the current marking sequence p of the character string marking sequence MS is determined to be n. That is, it may be determined as MS(p)=n. Here, the reference position RP may refer to a start point of a character that first starts marking among the characters included in the marking character string.

In operation S1403, a path for marking the corresponding character is added to an nth marking path. For example, a path for marking from a start point to an end point of the character corresponding to the current marking sequence p is determined as a p first path, and the nth marking path may be updated by adding the p first path to the nth marking path.

In operation S1405, the method may include searching for start point of a next character closest to the end point of the current character. For example, a marking position may be moved from the character on which marking ends to the next character to be marked. The marking sequence of characters included in the marking character string may be determined using a greedy search. For example, using the greedy search, the next character to be marked may be determined as the closest character to each of characters on which marking ends.

The marking position may be moved to a character having the closest start point to a position where marking ends. For example, a character including a start point of the closest position to the end point at which marking of the pth character ends in operation S1405, among start points of characters not yet included in the character string marking sequence MS, is determined as a (p+1) character. A start point of the (p+1) character may be defined as a (p+1) start point. A path for moving from the end point of the pth character to the (p+1) start point may be determined as a p second path, and the nth marking path may be updated by adding the p second path to the nth marking path.

In addition, a (p+1) element of the character string marking sequence MS may be determined as a number of the (p+1) character. Here, the character number refer to a number indicating a position or a sequence of the corresponding character in the marking character string.

In operation S1407, a marking path of the (p+1) character is added to the nth marking path. For example, a path for marking from the start point to the end point of the (p+1) character may be determined as a (p+1) first path, and the nth marking path may be updated by adding the (p+1) first path to the nth marking path.

In operation S1409, it is inspected whether all characters included in the marking character string have been added to the marking path. For example, it may be inspected whether a value of (p+1) in operation S1407 is the same as N which is the length of the entire character string, and in an example case in which the value of (p+1) is not the same as N in operation S1411, a p value may be updated to (p+1) in operation S1405, and then operations S1407 and S1409 may be sequentially performed again.

In an example case in which the value of (p+1) is the same as N which is the length of the entire character string in operation S1409, the process proceeds to operation S1413. The value of (p+1) being the same as N which is the length of the entire character string means that all characters of the marking character string are included in the marking path. At this time, the nth marking path may refer to the optimal path for marking the characters sequentially by using the nth character determined in operations S1401 to S1407 as a reference character.

In operation S1413, the nth marking path is compared with the optimal path length OPL. In an example case in which the nth marking path is less than the optimal path length OPL (S1415), the optimal marking path is updated to the current nth marking path, and the process proceeds to operation S1417.

In an example case in which the nth marking path is not less than the optimal path length OPL, the optimal marking path is not updated, and the process proceeds to operation S1417.

In operation S1417, the value of n is updated to the value of (n+1).

In operation S1419, it is inspected whether all characters included in the marking character string have been included in the marking path. In an example case in which n is greater than N by comparing the value of n updated in operation S1417 with N which is the marking character string length SL, it is considered that all characters are included in the marking path, the final marking path is determined as the current optimal marking path in operation S150, and the process ends.

In an example case in which n is less than or equal to N by comparing the n value updated in operation S1417 with N which is the marking character string length SL, it is considered that all characters are not yet included in the marking path, the process returns to operation S1430, and the subsequent operations may be performed again.

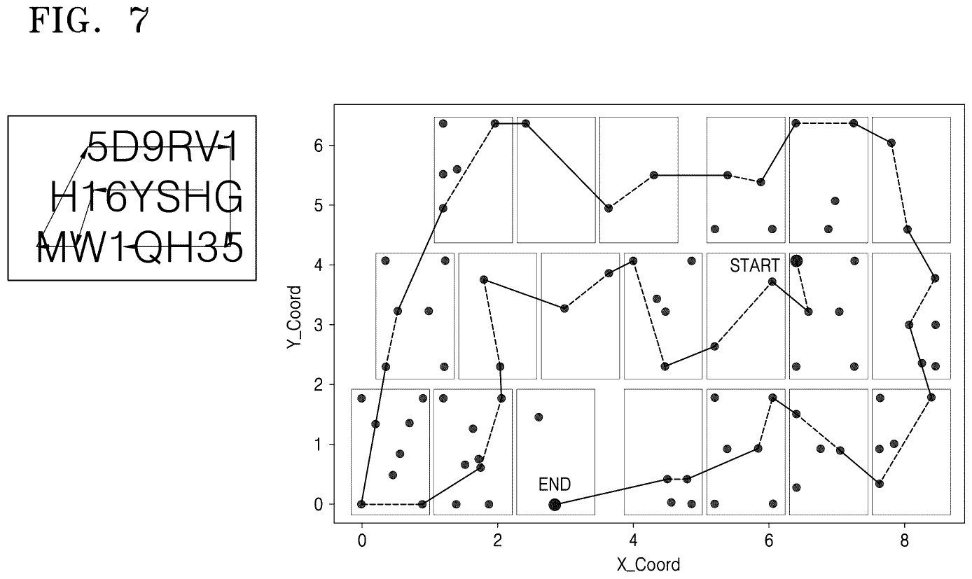

FIG. 7 is a conceptual diagram illustrating a laser marking path with respect to a marking character string according to a method of optimizing a laser marking path according to an embodiment.

Referring to FIG. 7, marking may be performed along a final marking path of the marking character string by using the method of optimizing the laser marking path described with reference to FIGS. 4 and 5. In the graph shown on the right, square boxes indicating the positions of characters and the positions of points of characters are shown as dots. Because a first path which is a marking path in one character is predetermined, the first path is simplified by connecting a start point to an end point in a dotted line. A second path which is a path for jumping and moving from an end point of one character to a start point of another character is shown in a solid line. In FIG. 7, it may be seen that the optimal marking path determined to start at H of a second line and end at 1 of a third line is determined as a final marking path in the marking character string including a total of three lines.

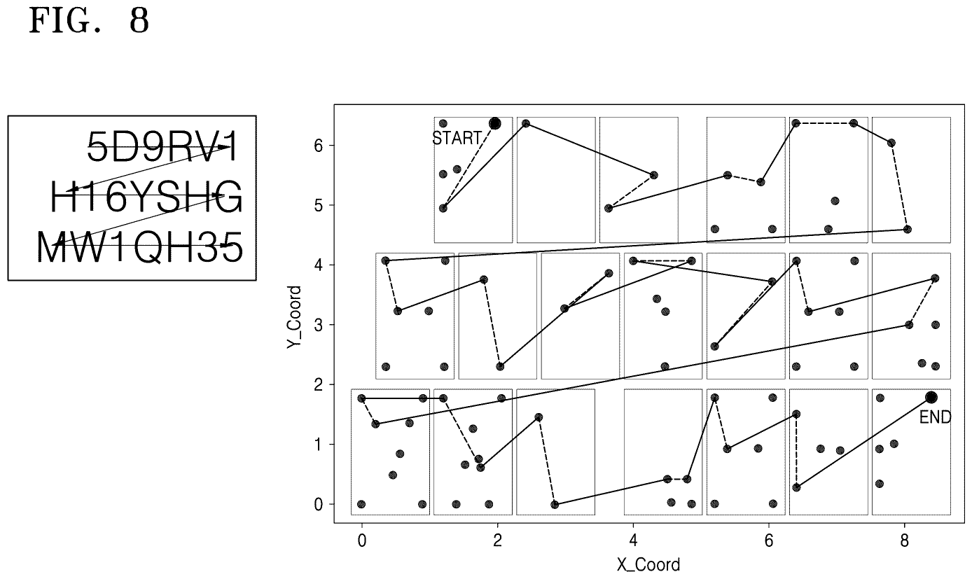

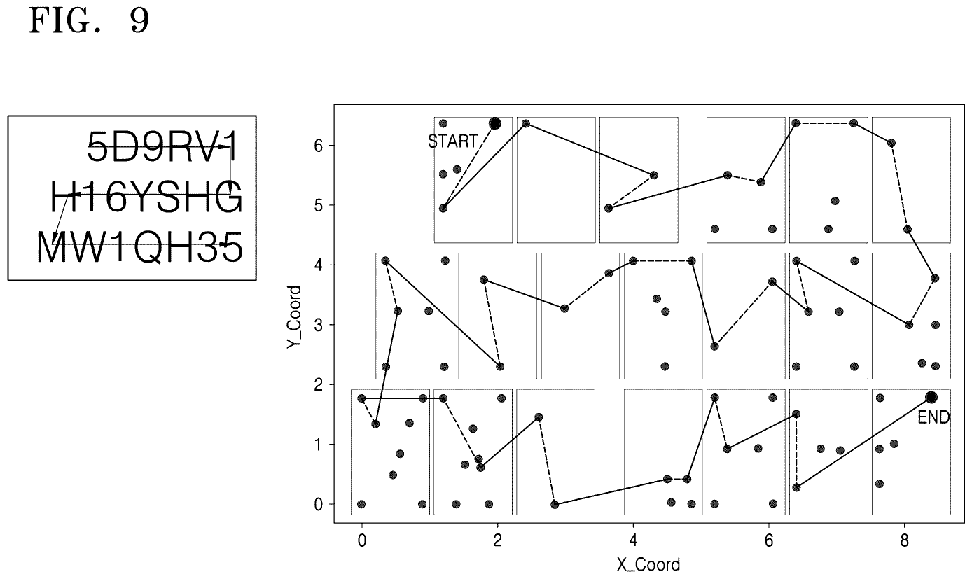

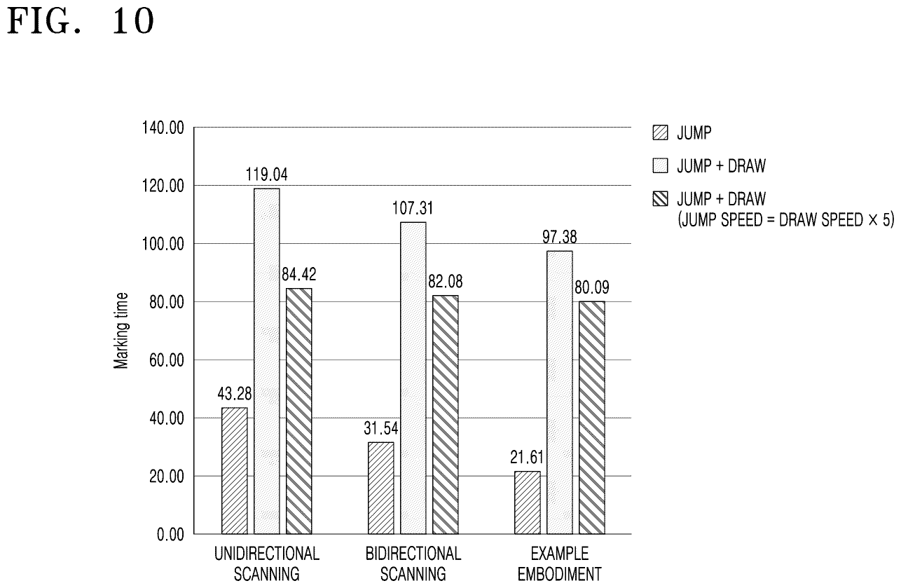

FIG. 8 is a conceptual diagram for explaining a laser marking path using unidirectional scanning. FIG. 9 is a conceptual diagram for explaining a laser marking path using bidirectional scanning. FIG. 10 is a graph for comparing laser marking speeds using a method of optimizing a laser marking path according to an embodiment, unidirectional scanning, and bidirectional scanning.

FIGS. 8 and 9 are conceptual diagrams for comparing the laser marking path according to a method of optimizing the laser marking path according to an embodiment with a marking path of FIG. 7.

Referring to FIG. 8, a laser marking device may form a marking path by moving from left to right and from top to bottom of a marking character string using a unidirectional marking path. Referring to FIG. 9, the laser marking device may form a marking path by moving from top to bottom of the marking character string, and alternately moving from left to right and from right to left using a bidirectional marking path

Referring to FIG. 10, the laser marking speeds may be compared using the marking paths of FIGS. 7 to 9. FIG. 10 is the graph comparing times when randomly generated marking character strings are marked according to the respective methods. In each method, a first bar refers to the time required for the laser marking device to simply move (jump) along a path, and a second bar refers to the time required for the laser marking device to mark (draw) characters and move (jump) between the characters. A third bar represents the marking and movement times in an example case in which a speed (jump speed) at which the laser marking device moves without marking is five times faster than a marking speed (draw speed).

In an example case in which the laser marking device only moves along the final marking path determined by the method of optimizing the laser marking path in the randomly generated marking character strings according to an embodiment of the disclosure, the time required may be reduced by about 50 % when compared to the unidirectional scanning method and about 32 % when compared to the bidirectional scanning method. In addition, considering the marking speed of the laser marking device, in an example case in which the laser marking device marks the characters and moves between the characters, the time required may be reduced by about 5.13 % when compared to the unidirectional scanning method and about 2.42 % when compared to the bidirectional scanning.

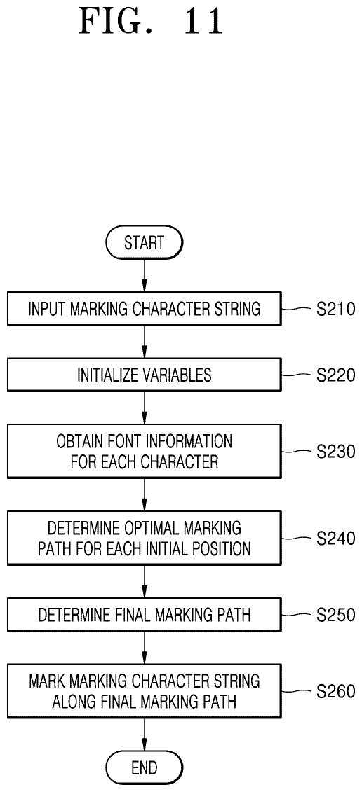

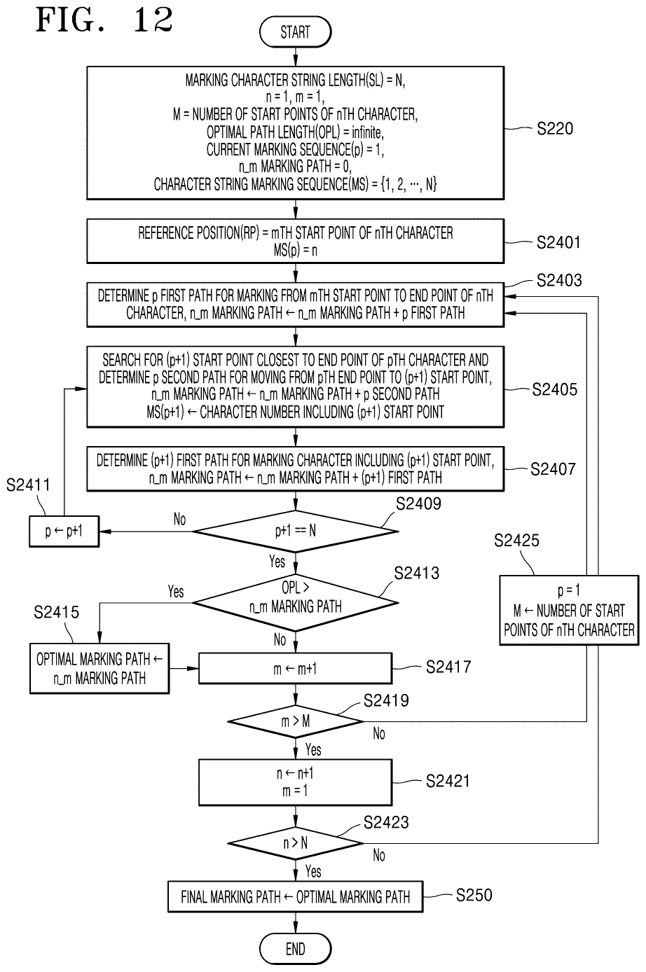

FIG. 11 is a flowchart schematically illustrating a method of optimizing a laser marking path according to an embodiment. FIG. 12 is a flowchart illustrating an algorithm for determining a final marking path according to an embodiment.

In comparison with the method of optimizing a laser marking path described with reference to FIGS. 4 and 5, in FIGS. 11 and 12, the optimal marking path may be determined when marking starts at each of start points included in each character. For convenience of explanation, the differences between the method of optimizing the laser marking path of FIGS. 11 and 12 and the method of optimizing the laser marking path of FIGS. 4 and 5 are mainly described. Each of operations of optimizing the laser marking path of FIGS. 11 and 12 may be performed by the processor 114 of FIG. 3.

Referring to FIG. 11, a marking character string may be input in operation S210. For example, the marking character string may be received by the laser marking device.

In operation S220, variables necessary to determine the optimal marking path are initialized. Here, the variable may include information about the length of the marking character string, the marking sequence of characters included in the marking character string, a reference character which is a character starting marking among the characters included in the marking character string, and an initial position which is a character starting marking within the reference character. For example, the variables may be initialized to set the length of the marking character string to the number of characters of the marking character string input in operation S210. In addition, for example, the variables may be initialized to set the marking sequence to the sequence in which the characters of the marking character string are arbitrarily listed, set the reference character to a first character, and set the initial position to a first start point of the reference character.

In operation S230, font information for each character may be obtained. The font information for each character may include points, start points, and end points for each character. According to an embodiment, the font information for each character may include a plurality of start points for each character, and may include information about end points respectively corresponding to the start points.

In FIG. 11, operations S210, S220, and S230 are shown as separate steps, but are not necessarily performed in sequence, and operations S220 and S230 may be performed simultaneously with operation S210, or operation S230 may be performed before operation S220.

In operation S240, the optimal marking path for each initial position may be determined. Here, the initial position may refer to a point at which marking starts in each character of a marking character string. Referring to FIG. 6, in an example case in which the marking character string is “5D9RV1”, the initial positions in a first character “5” may be a first point, a fourth point, and a fifth point. Because a second character “D” includes only one point, the initial position may be the first point. Similarly, in the marking character string “5D9RV1” including a total of six characters, the optimal marking paths may be determined when marking starts at the initial positions of each character.

In operation S250, the most optimal path among the optimal marking paths determined in operation S240 may be determined as the final marking path.

In operation S260, the laser marking device 10 (see FIG. 1) may mark the marking character string on the marking region 250 (see FIG. 1) of the semiconductor package 20 (see FIG. 1) with a laser along the determined final marking path.

FIG. 12 illustrates an algorithm for performing operations S220, S240, and S250 of FIG. 11 in more detail.

In operation S220, variables necessary to determine the optimal marking path are initialized. In an example case in which the number of characters in the marking character string is N, an initial value of the marking character string length SL is determined to be N. An initial value of the optimal path length OPL is determined to be infinite. An initial value of a variable n for determining which of the characters to start marking is determined to be 1. The variable M is determined by the number of start points of the nth character. An initial value of a variable m for determining which of the start points of the nth character to start marking is determined to be 1, and an initial value of the variable p for indicating the sequence of the characters determining the current marking path is determined to be 1. Here, n and p may be integers greater than or equal to 1 and less than or equal to N. m may be an integer greater than or equal to 1 and less than or equal to M. An n_m marking path is a variable that refers to a path for marking all characters included in the marking character string from an mth start point of the nth character, and the initial value is determined to be 0. Here, the path may refer to a length of a path to be marked. The character string marking sequence MS may refer to a permutation for indicating the sequence of N characters. In an example case in which marking is performed from the first character in sequence listed in the character string, it may be expressed as the character string marking sequence MS={1, 2, . . . , N}. The initial value of the character string marking sequence MS may be arbitrarily determined as MS={1, 2, . . . , N}.

Operations S2401 to S2425 are detailed operations of operation S240 of FIG. 11. Hereinafter, the first path may refer to a path through which the laser marking device moves to draw one character, and the second path may refer to a path through which the laser marking device jumps and moves from one character to a marking position of another character.

In operation S2401, the reference position RP is defined as the mth start point of the nth character, and an element corresponding to the current marking sequence p of the character string marking sequence MS is determined to be n. That is, it may be determined as MS(p)=n. Here, the reference position RP may refer to a start point of a character that first starts marking among the characters included in the marking character string.

In operation S2403, a path for marking the mth start point to an end point of the corresponding character is added to the n_m marking path. For example, a path for marking from the mth start point to the ending point of the character corresponding to the current marking sequence p is determined as the p first path, and the n_m marking path may be updated by adding the p first path to the n_m marking path.

In operation S2405, marking position may be moved from the character on which marking ends to the next character to be marked. The marking sequence of characters included in the marking character string may be determined using a greedy search. For example, using the greedy search, the next character to be marked may be determined as a character including the closest start point to an end point of each of characters on which marking ends.

The marking position may be moved to a character having the closest start point from a position where marking has ended. For example, a character including a start point of the closest position to the end point at which marking of the pth character ends in operation S2405, among start points of characters not yet included in the character string marking sequence MS, is determined as the (p+1) character. A start point of the (p+1) character may be defined as the (p+1) start point. A path for moving from the end point of the pth character to the (p+1) start point may be determined as the p second path, and the n_m marking path may be updated by adding the p second path to the n_m marking path.

In addition, the (p+1) element of the character string marking sequence MS may be determined as a number of the (p+1) character. Here, the character number refer to a number indicating a position or a sequence of the corresponding character in the marking character string.

In operation S2407, a marking path of the (p+1) character is added to the n_m marking path. For example, a path for marking from the start point to the end point of the (p+1) character may be determined as the (p+1) first path, and the n_m marking path may be updated by adding the (p+1) first path to the n_m marking path.

In operation S2409, it is inspected whether all characters included in the marking character string have been added to the marking path. For example, it may be inspected whether the value of (p+1) in operation S2407 is the same as N which is the length of the entire character string, and in an example case in which the value of (p+1) is not the same as N in operation S2411, the p value may be updated to (p+1) in operation S2405, and then operations S2407 and S2409 may be sequentially performed again.

In an example case in which the value of (p+1) is the same as N which is the length of the entire character string in operation S2409, the process proceeds to operation S2413. The value of (p+1) being the same as N which is the length of the entire character string means that all characters of the marking character string are included in the marking path. At this time, the n_m marking path may refer to the optimal path for marking characters sequentially by using the mth start point of the nth character determined in operations S2401 to S2407 as an initial position.

In operation S2413, the n_m marking path is compared with the optimal path length OPL. In an example case in which the n_m marking path is less than the optimal path length OPL (S2415), the optimal marking path is updated to the current n_m marking path, and the process proceeds to operation S2417.

In an example case in which the n_m marking path is not less than the optimal path length OPL, the optimal marking path is not updated, and the process proceeds to operation S2417.

In operation S2417, the value of m is updated to the value of (m+1).

In operation S2419, it is inspected whether each optimal marking path has been determined by using all the start points of the nth character as initial positions. In an example case in which the value of m updated in operation S2417 is less than or equal to the value of M which is the number of start points of the nth character (S2425), the value of p which is the variable representing the current marking sequence is updated to 1, the process returns to operation S2403, and the subsequent operations may be performed again.

In operation S2419, based on the value of m being greater than the value of M (S2421), the value of n is updated to the value of (n+1), and the value of m is updated to 1. For example, when the value of m is greater than the value of M (S2421), the value of n is updated to the value of (n+1), and the value of m is updated to 1.

In operation S2423, it is inspected whether all characters included in the marking character string have been included in the marking path. For example, based on n being greater than N in a comparison between the value of n updated in operation S2421 and N which is the marking character string length SL, it is considered that all characters are included in the marking path, the final marking path is determined as the current optimal marking path in operation S250, and the process ends.

For example, based on n being less than or equal to N in the comparison between the n value updated in operation S2421 and N which is the marking character string length SL, it is considered that all characters are not yet included in the marking path, in operation S2425, the value of p which is the variable representing the current marking sequence is updated to 1, the value of M is updated to the number of start points of the nth character, the process returns to operation S2403, and the subsequent operations may be performed again.

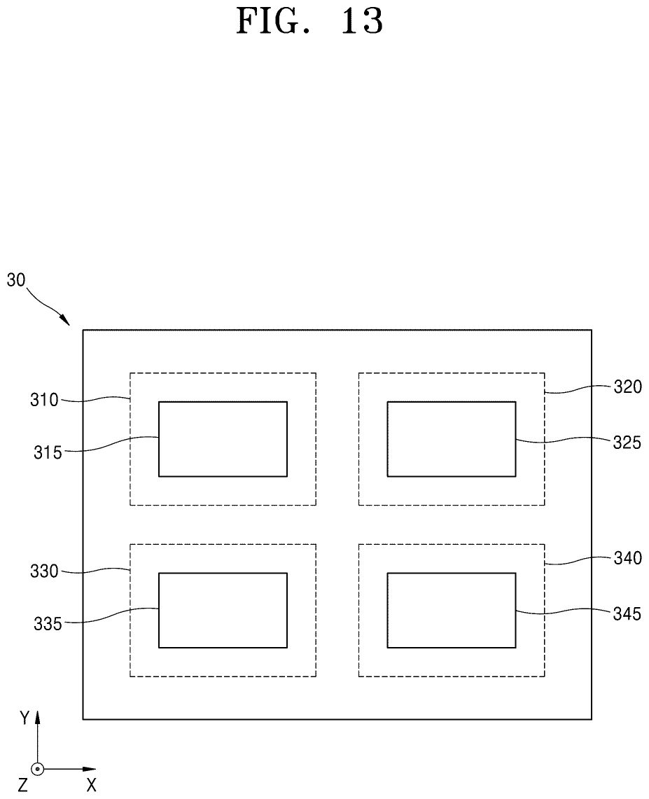

FIG. 13 is a plan view schematically illustrating a semiconductor package 30 according to an embodiment. FIG. 13 is the plan view illustrating only semiconductor chips 310, 320, 330, and 340 and first to fourth marking regions 315, 325, 335, and 345 while omitting other components of the semiconductor package 30.

Referring to FIG. 13, the semiconductor package 30 may include the plurality of semiconductor chips 310, 320, 330, and 340, and may include the first to fourth marking regions 315, 325, 335, and 345 respectively corresponding to the plurality of semiconductor chips 310, 320, 330, and 340.

Each of the first to fourth marking regions 315, 325, 335, and 345 is a position for forming a marking character string with the laser marking device 10 (see FIG. 1). The semiconductor package 30 of FIG. 13 includes the first to fourth marking regions 315, 325, 335, and 345, thereby forming the marking character string in each of the first to fourth marking regions 315, 325, 335, and 345. In the semiconductor package 30 of FIG. 13, the four semiconductor chips 310, 320, 330, and 340 and the first to fourth marking regions 315, 325, 335, and 345 respectively corresponding thereto are shown, but the disclosure is not limited thereto, and the semiconductor package 30 may include two or more semiconductor chips and marking regions.

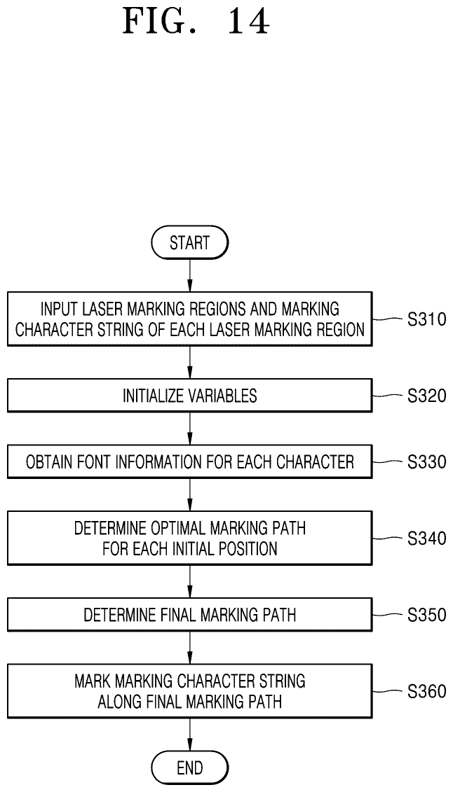

FIG. 14 is a flowchart schematically illustrating a method of optimizing a laser marking path according to an embodiment.

FIG. 14 schematically illustrates the method of optimizing the laser marking path to form the entire marking character string included in all the marking regions 315, 325, 335, and 345 of FIG. 13. The method of optimizing the laser marking path of FIG. 14 is different from the method of optimizing the laser marking path described with reference to FIGS. 4 and 11 in that marking character strings are provided on a plurality of laser marking regions, but the remaining components are similar to those described with reference to FIGS. 4 and 11. For convenience of explanation, the differences between the method of optimizing the laser marking path of FIG. 14 and the method of optimizing the laser marking path of FIGS. 4 and 11 are mainly described. Each of operations of optimizing the laser marking path of FIG. 14 may be performed by the processor 114 of FIG. 3.

Referring to FIG. 14, in operation S310, laser marking regions and marking character strings of the respective laser marking regions may be input. For example, the laser marking regions may include the first marking region 315, the second marking region 325, the third marking region 335, and the fourth marking region 345 of FIG. 13. The marking character string includes characters to be marked in each laser marking region.

In operation S320, variables necessary to determine the optimal marking path are initialized. Here, variables may include information about the length of the marking character string, the marking sequence of the laser marking regions, the marking sequence of characters included in the marking character string, and a reference character, which is a character that starts marking, among the characters included in the marking character string.

In operation S330, font information for each character may be obtained.

Operations S310, S320, and S330 are shown as separate steps, but are not necessarily performed in sequence, and operations S320 and S330 may be performed simultaneously with operation S310, or operation S330 may be performed before operation S320.

In operation S340, the optimal marking path for each initial position may be determined. Here, the initial position may refer to a laser marking region in which a laser marking device starts marking the marking character string. According to some embodiments, the initial position may refer to a position at which the laser marking device starts marking within an arbitrary laser marking region.

In some embodiments, the optimal marking path may mean that the length of the entire marking path is the minimum. Here, the entire marking path may refer to a path for marking the entire marking character string of all laser marking regions. For example, the optimal marking path may be determined such that the sum of first paths through which the laser marking device moves to mark each character included in a marking character string within each laser marking region, second paths through which the laser marking device moves from a completely marked character to a next character within the marking character string, and third paths through which the laser marking device moves from a completely marked region to a next laser marking region is minimized.

In an example case in which the same marking character string is marked with a laser in each laser marking region, the marking path of each character string may be optimized first through the methods described with reference to FIGS. 4 and 5, or FIGS. 11 and 12. In an example case in which the same marking character string “5D9RV1” is marked in the first marking region 315, the second marking region 325, the third marking region 335, and the fourth marking region 345 of FIG. 13, the optimal marking path of the marking character string within each marking region may be determined through one optimization algorithm. The optimal marking path of the marking character string within each marking region may be determined such that the sum of the first paths through which the laser marking device moves to mark each character and the second paths through which the laser marking device moves from the completely marked character to the next character within the marking character string is minimized. The entire marking path, that is, a path for marking all marking character strings included in the first marking region 315, the second marking region 325, the third marking region 335, and the fourth marking region 345 is determined such that the sum of the third paths through which the laser marking device moves between the marking regions is minimized.

The marking sequence of the marking regions may be determined using a greedy search. In an example case in which marking starts in the first marking region 315, a marking path may be formed from a point where marking of the first marking region 315 ends to a start point of the second marking region 325 which has the closest marking start point is located (such that the third path is the minimum). Optimal marking paths may be determined while changing the initial position to the start point of each marking region. According to one or more embodiments, the laser marking device may consider all marking character strings as one target marking character string without dividing marking character strings in each laser marking region unit, and determine the optimal marking path. For example, the optimal marking path may be determined such that the sum of the first paths from the start point to the end point and the second paths from the completely marked character to the next character is minimized, in order for the laser marking device to mark each character in the marking character strings included in all the laser marking regions. In this case, the optimal marking path may be determined through the method described with reference to FIGS. 4 and 5, or in FIGS. 11 and 12.

In operation S350, the final marking path is determined. The most optimal path among the optimal marking paths determined in operation S340 may be determined as the final marking path. For example, the shortest path among the final marking paths may be determined as the final marking path. In another example, a path through which the shortest time is required among the final marking paths may be determined as the final marking path.

In operation S360, the laser marking device 10 (see FIG. 1) may mark the marking character strings on the first to fourth laser marking regions 315, 325, 335, and 345 (see FIG. 13) of the semiconductor package 20 (see FIG. 1) with the laser along the determined final marking path.

While the inventive concept has been particularly shown and described with reference to embodiments thereof, it will be understood that various changes in form and details may be made therein without departing from the spirit and scope of the following claims.

What is claimed is:

1. A method of minimizing a laser marking path, the method comprising:
receiving a marking character string;
obtaining marking font information for each of a plurality of characters in the marking character string;
determining a plurality of candidate optimal marking paths for marking the marking character string based on the marking font information, each of the plurality of candidate optimal marking paths corresponding to a laser marking device starting marking at one of the plurality of characters in the marking character string; and
determining a shortest path among the plurality of candidate optimal marking paths as a final marking path.

2. The method of claim 1, wherein the marking font information comprises:
a start point comprising first position information where the laser marking device starts marking of a first character; and
an end point comprising second position information where the laser marking device ends marking of the first character.

3. The method of claim 1, wherein the plurality of candidate optimal marking paths are based on a sum of first paths through which the laser marking device moves to mark each of the plurality of characters in the marking character string and second paths through which the laser marking device moves from a completely marked character to a next character is minimized.

4. The method of claim 1, wherein the plurality of candidate optimal marking paths are based on a sum of first times required for the laser marking device to move to mark each of the plurality of characters in the marking character string and second paths required for the laser marking device to move from a completely marked character to a next character is minimized.

5. The method of claim 1, wherein the determining of the plurality of candidate optimal marking paths comprises determining a marking sequence of the plurality of characters in the marking character string, by using a greedy search.

6. The method of claim 2, wherein the determining of the plurality of candidate optimal marking paths comprises:
adding each of the plurality of characters in the marking character string to a marking sequence one by one, and
wherein a next character in the marking sequence is determined as a character having a closest start point to an end point of one character among start points of characters of the marking character string that are not yet included in the marking sequence.

7. The method of claim 1, further comprising:
initializing variables of the marking character string, the variables comprising a length of a marking path and a marking sequence of the plurality of characters in the marking character string, and
wherein the determining of the plurality of candidate optimal marking paths comprises:
adding, to the length of the marking path, a length of a first path through which the laser marking device moves to mark each of the plurality of characters in the marking character string and a length of a second path through which the laser marking device moves from a completely marked character to a next character, and
updating the next character to the marking sequence.

8. The method of claim 7, wherein
the variables comprise a reference character which is a character starting marking of the marking character string, and
the determining of the plurality of candidate optimal marking paths comprises:
updating the reference character sequentially from a first character to a last character of the marking character string, and
determining an optimal marking path with respect to the updated reference character.

9. The method of claim 1, further comprising:
performing marking based on the final marking path.

10. A method of minimizing a laser marking path, the method comprising:
receiving a marking character string;
obtaining marking font information for each of a plurality of characters in the marking character string, the marking font information comprising a plurality of reference points, one or more start points, and one or more end points, each of the plurality of reference points comprising position information for defining a first path through which a laser marking device moves to mark a respective character among the plurality of characters, the one or more start points indicate a position at which the laser marking device starts marking of the character among the plurality of reference points, and the one or more end points indicate a position at which the laser marking device ends marking of the character corresponding to the one or more start points;
determining a plurality of candidate optimal marking paths for marking the marking character string based on the marking font information, each of the plurality of candidate optimal marking paths corresponding to a laser marking device starting marking at one of the plurality of characters in the marking character string; and
determining a shortest path among the plurality of candidate optimal marking paths as a final marking path.

11. The method of claim 10, wherein the plurality of candidate optimal marking paths are based on a sum of first paths through which the laser marking device moves to mark each of the plurality of characters in the marking character string and second paths through which the laser marking device moves from a completely marked character to a next character is minimized.

12. The method of claim 10, wherein the plurality of candidate optimal marking paths are based on a sum of first times required for the laser marking device to move to mark each of the plurality of characters in the marking character string and second paths required for the laser marking device to move from a completely marked character to a next character is minimized.

13. The method of claim 10, wherein the determining of the plurality of candidate optimal marking paths comprises determining a marking sequence of the plurality of characters in the marking character string, by using a greedy search.

14. The method of claim 10, wherein the determining of the plurality of candidate optimal marking paths comprises: adding each of the plurality of characters in the marking character string to a marking sequence one by one, and
wherein a next character in the marking sequence is determined as a character having a closest start point to an end point of one character among one or more start points of characters of the marking character string that are not yet included in the marking sequence.

15. The method of claim 10, further comprising:
initializing variables of the marking character string, the variables comprising a length of a marking path and a marking sequence of the plurality of characters in the marking character string, and
wherein the determining of the plurality of candidate optimal marking paths comprises:
adding, to the length of the marking path, a length of a first path through which the laser marking device moves to mark each of the plurality of characters in the marking character string and a length of a second path through which the laser marking device moves from a completely marked character to a next character, and
updating the next character to the marking sequence.

16. The method of claim 15, wherein
the variables comprise a reference character which is a character starting marking of the marking character string; and an initial position of a start point which is a position where marking starts within the reference character, and
the determining of the plurality of candidate optimal marking paths comprises:
determining the plurality of candidate optimal marking paths for each initial position by updating the initial position for each reference character sequentially from a first start point to a last start point of the reference character;
updating the reference character sequentially from a first character to a last character of the marking character string; and
determining a minimum path among the plurality of candidate optimal marking paths for each initial position as an optimal marking path according to the reference character.

17. The method of claim 10, further comprising: performing marking based on the final marking path.

18. A method of minimizing a laser marking path, the method comprising:
receiving laser marking regions and marking character strings to be marked respectively on the laser marking regions;
obtaining marking font information for each of a plurality of characters in the marking character strings;
determining a plurality of candidate optimal marking paths for marking the marking character strings in the laser marking regions based on the marking font information, each of the plurality of candidate optimal marking paths corresponding to a laser marking device starting marking at one of the plurality of characters in the marking character strings; and
determining a shortest path among the plurality of candidate optimal marking paths as a final marking path.

19. The method of claim 18, wherein the marking font information comprises:
a start point comprising first position information where the laser marking device starts marking of a first character; and
an end point comprising second position information where the laser marking device ends marking of the first character,
wherein the plurality of candidate optimal marking paths are based on a sum of first paths through which the laser marking device moves from a start point to an end point to mark each of the plurality of characters in the marking character string in each of the laser marking regions, second paths through which the laser marking device moves from a completely marked character to a next character within the marking character string, and third paths through which the laser marking device moves from a completely marked laser marking region to a next laser marking region is minimized.

20. The method of claim 18, wherein
the marking font information comprises a plurality of reference points, one or more start points, and one or more end points, each of the plurality of reference points comprising position information for defining a first path through which a laser marking device moves to mark a first character, the one or more start points indicate a position at which marking of the character starts among the plurality of reference points, and the one or more end points indicate position at which marking of the character ends corresponding to the one or more start points, and
the plurality of candidate optimal marking paths are based on a sum of first paths through which the laser marking device moves from a start point to an end point to mark each of the plurality of characters in the marking character strings in all the laser marking regions, and second paths through which the laser marking device moves from the completely marked character to a next character is minimized.
